(19) United States
(12) Patent Application Publication
(10) Pub. No.: US 2025/0382704 A1
(43) Pub. Date: Dec. 18, 2025

(54) FILM FORMING METHOD AND FILM FORMING APPARATUS

(71) Applicant: TOKYO ELECTRON LIMITED, Tokyo (JP)

(72) Inventors: Yumiko KAWANO, Nirasaki City, Yamanashi (JP); Zeyuan NI, Nirasaki City, Yamanashi (JP); Shuji AZUMO, Nirasaki City, Yamanashi (JP); Taiki KATO, Nirasaki City, Yamanashi (JP)

(21) Appl. No.: 18/684,088

(22) PCT Filed: Aug. 8, 2022
(86) PCT No.: PCT/JP2022/030226

§ 371 Date: Mar. 24, 2025

(30) Foreign Application Priority Data
Aug. 16, 2021 (JP) 2021-132242

(51) Int. Cl. C23C 16/455; C23C 16/04; C23C 16/40; C23C 16/458; C23C 16/52

(52) U.S. Cl. CPC C23C 16/45544; C23C 16/042; C23C 16/045; C23C 16/403; C23C 16/405; C23C 16/458; C23C 16/52

(57) ABSTRACT

A film forming method includes (A) to (C) as follows. (A) A substrate having a first region on which a first insulating film is exposed and a second region on which a metal film is exposed, is prepared on a surface of the substrate. (B) An organic compound including an isothiocyanate group (NCS group) as a head group, which is a raw material of a self-assembled monolayer, is supplied to the surface of the substrate, and the self-assembled monolayer is formed by selectively adsorbing the organic compound onto the second region among the first region and the second region. (C) A raw material gas, which is a raw material of a second insulating film, is supplied to the surface of the substrate, and the second insulating film is formed in the first region while inhibiting formation of the second insulating film in the second region using the self-assembled monolayer.

### TECHNICAL FIELD

The present disclosure relates to a film forming method and a film forming apparatus.

### BACKGROUND

Patent Document 1 discloses forming a self-assembled monolayer (SAM) on a surface of a substrate and using an isothiocyanate group as an example of a head group of an organic compound which is a raw material for the SAM. Similar content is also disclosed in Patent Document 2.

### PRIOR ART DOCUMENTS

### Patent Documents

Patent Document 1: U.S. Pat. No. 10,782,613
Patent Document 2: Japanese Patent Laid-Open Publication No. 2013-508989

### SUMMARY

One aspect of the present disclosure provides a technique for selectively forming a SAM in a metal film among the metal film and an insulating film.

According to an embodiment of the present disclosure, a film forming method includes (A) to (C) as follows. (A) A substrate having a first region on which a first insulating film is exposed and a second region on which a metal film is exposed, is prepared on a surface of the substrate. (B) An organic compound including an isothiocyanate group (NCS group) as a head group, which is a raw material of a self-assembled monolayer, is supplied to the surface of the substrate, and the self-assembled monolayer is formed by selectively adsorbing the organic compound onto the second region among the first region and the second region. (C) A raw material gas, which is a raw material of a second insulating film, is supplied to the surface of the substrate, and the second insulating film is formed in the first region while inhibiting formation of the second insulating film in the second region using the self-assembled monolayer.

According to the present disclosure, it is possible to selectively form a SAM in a metal film among the metal film and an insulating film.

### BRIEF DESCRIPTION OF DRAWINGS

FIG. 1 is a flowchart illustrating a film forming method according to an embodiment.

FIG. 2A is a diagram illustrating a state (step S1) of a substrate according to the embodiment.

FIG. 2B is a diagram illustrating a state (step S2) of the substrate according to the embodiment.

FIG. 2C is a diagram illustrating a state (step S3) of the substrate according to the embodiment.

FIG. 3A is a diagram illustrating a state (step S1) of the substrate according to a first modification.

FIG. 3B is a diagram illustrating a state (step S2) of the substrate according to the first modification.

FIG. 3C is a diagram illustrating a state (step S3) of the substrate according to the first modification.

FIG. 4A is a diagram illustrating a state (step S1) of the substrate according to a second modification.

FIG. 4B is a diagram illustrating a state (step S2) of the substrate according to the second modification.

FIG. 4C is a diagram illustrating a state (step S3) of the substrate according to the second modification.

FIG. 5 is a plan view illustrating a film forming apparatus according to an embodiment.

FIG. 6 is a cross-sectional view illustrating an example of a first processor in FIG. 5.

FIG. 7 is a diagram illustrating results obtained by measuring, using XPS, a surface state of a Cu substrate obtained from Experimental Example 1.

FIG. 8 is a diagram illustrating results obtained by measuring, using XPS, the surface state of the Cu substrate obtained from Experimental Example 2.

FIG. 9 is a diagram illustrating results obtained by measuring, using XPS, surface states of various substrates obtained from Experimental Example 3.

FIG. 10 is a diagram illustrating comparison between results of a Cu substrate and a SiO film in FIG. 9.

FIG. 11 is a diagram illustrating comparison between results of a Co film and the SiO film in FIG. 9.

FIG. 12 is a diagram illustrating comparison between results of a Ru film and the SiO film in FIG. 9.

FIG. 13 is a diagram illustrating comparison between results of a W film and the SiO film in FIG. 9.

FIG. 14 is a diagram illustrating comparison between results of a TiN film and the SiO film in FIG. 9.

FIG. 15 is a diagram illustrating results obtained by measuring, using XPS, surface states of various substrates obtained from Reference Example 1.

FIG. 16 is a diagram illustrating comparison between results of a Cu substrate and a SiO film in FIG. 15.

FIG. 17 is a diagram illustrating comparison between results of a Co film and the SiO film in FIG. 15.

FIG. 18 is a diagram illustrating comparison between results of a Ru film and the SiO film in FIG. 15.

FIG. 19 is a diagram illustrating comparison between results of a W film and the SiO film in FIG. 15.

FIG. 20 is a diagram illustrating comparison between results of a TiN film and the SiO film in FIG. 15.

### DETAILED DESCRIPTION

Embodiments of the present disclosure will now be described with reference to the accompanying drawings. In each drawing, the same or corresponding component elements are denoted by the same reference numerals, and descriptions thereof may be omitted.

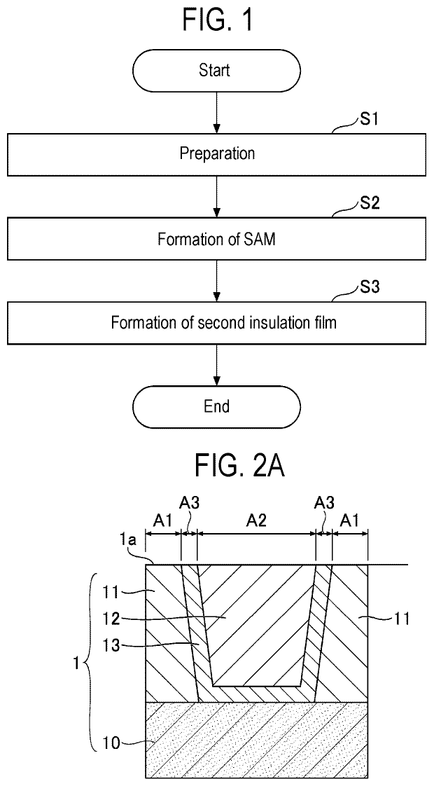

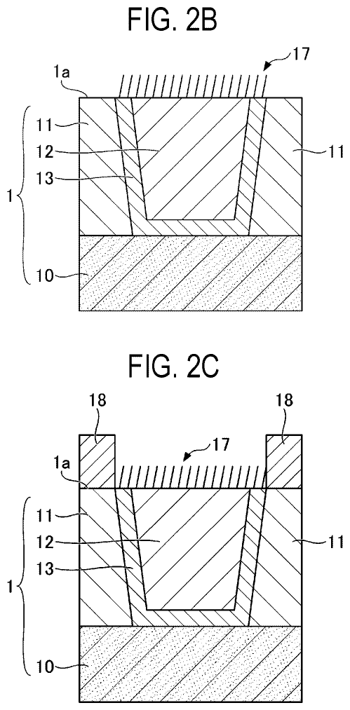

First, a film forming method according to the present embodiment will be described with reference to FIG. 1 and FIGS. 2A to 2C. The film forming method includes, for example, steps S1 to S3 illustrated in FIG. 1. The film forming method may include other steps in addition to steps S1 to S3. Further, the film forming method may include repeating steps S2 to S3 multiple times.

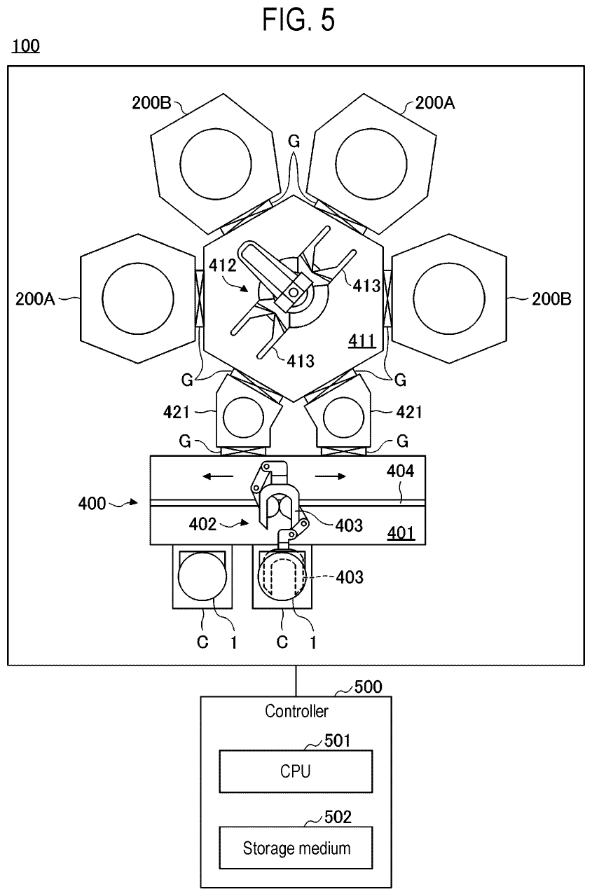

First, in step S1 of FIG. 1, a substrate 1 is prepared, as illustrated in FIG. 2A. Preparing the substrate 1 includes, for example, loading a carrier C into a film forming apparatus 100 illustrated in FIG. 5. The carrier C accommodates a plurality of substrates 1.

The substrate 1 includes a base substrate 10, such as a silicon wafer or a compound semiconductor wafer. The compound semiconductor wafer is not particularly limited and may be, for example, a GaAs wafer, a SiC wafer, a GaN wafer, or an InP wafer.

The substrate 1 includes an insulating film 11 formed on the base substrate 10. A conductive film may be formed between the insulating film 11 and the base substrate 10. The insulating film 11 is, for example, an interlayer insulating film. The interlayer insulating film may be a low dielectric constant (low-k) film.

The insulating film 11 is not particularly limited and may be, for example, a SiO film, a SiN film, a SiOC film, a SiON film, or a SiOCN film. Here, the SiO film means a film containing silicon (Si) and oxygen (O). An atomic ratio of Si to O in the SiO film is not limited to 1:1. This holds true in the SiN film, the SiOC film, the SiON film, and the SiOCN film. The insulating film 11 has a recess formed in a surface 1a of the substrate 1. The recess is a trench, a contact hole, or a via hole

The substrate 1 includes a metal film 12 filled into the recess. The metal film 12 is not particularly limited and may be, for example, a Cu film, a Co film, a Ru film, or a W film.

The substrate 1 further includes a barrier film 13 formed along the recess. The barrier film 13 suppresses diffusion of metal from the metal film 12 to the insulating film 11. The barrier film 13 is not particularly limited and may be, for example, a TaN film or a TiN film. Here, the TaN film means a film containing tantalum (Ta) and nitrogen (N). An atomic ratio of Ta to N in the TaN film is not limited to 1:1. This also holds true in the TiN film.

Table 1 summarizes specific examples of the insulating film 11, the metal film 12, and the barrier film 13.

TABLE 1

| Insulating film | Metal film | Barrier film |
|---|---|---|
| SiO film | Cu film | TaN film |
| SiN film | Co film | TiN film |
| SiOC film | Ru film | |
| SiON film | W film | |
| SiOCN film | | |

A combination of the insulating film 11, the metal film 12, and the barrier film 13 is not particularly limited.

As illustrated in FIG. 2A, the substrate 1 has, on the surface 1a thereof, a first region A1 on which the insulating film 11 is exposed and a second region A2 on which the metal film 12 is exposed. The substrate 1 may further have, on the surface 1a thereof, a third region A3 on which the barrier film 13 is exposed. The third region A3 is formed between the first region A1 and the second region A2. A structure of the substrate 1 is not limited to the structure illustrated in FIG. 2A, as described below.

The substrate 1 may be subjected to a step of removing a natural oxide film prior to being subjected to step S2 of FIG. 1. The natural oxide film is formed on the surface of the metal film 12. The removal of the natural oxide film includes, for example, supplying a hydrogen (H2) gas to the surface 1a of the substrate 1. The hydrogen gas reduces and removes the natural oxide film. The hydrogen gas may be heated to a high temperature to facilitate a chemical reaction. The hydrogen gas may also be plasmarized to promote the chemical reaction.

The removal of the natural oxide film is not limited to dry processing on the surface 1a of the substrate 1 and may be performed through wet processing. For example, the natural oxide film may be removed by supplying solution, such as citric acid (C(OH)(CH₂COOH)₂COOH), to the surface 1a of the substrate 1. Thereafter, the substrate 1 is washed with pure water or the like and then dried.

Next, in step S2 of FIG. 1, as illustrated in FIG. 2B, an organic compound containing an isothiocyanate group, which is a raw material of a SAM 17, is supplied as a head group to the surface 1a of the substrate 1. The isothiocyanate group is more easily chemisorbed onto the metal film 12 than onto the insulating film 11. Therefore, the organic compound may be selectively chemisorbed onto the second region A2 among the first region A1 and the second region A2, so that the SAM 17 may be formed.

The isothiocyanate group is more easily chemisorbed even onto the barrier film 13 than onto the insulating film 11. Therefore, as illustrated in FIG. 2B, the organic compound may be selectively chemisorbed onto the second area A2 and the third area A3 among the first area A1, the second area A2, and the third area A3, so that the SAM 17 may be formed. Thus, the organic compound containing the isothiocyanate group as the head group may form the SAM 17 over a plurality of regions (e.g., the second region A2 and the third region A3).

The organic compound containing the isothiocyanate groups as the head group is represented by a general formula “R-NCS.” R is obtained by replacing, for example, a hydrocarbon group or at least a portion of hydrogen of the hydrocarbon group with a halogen element. Halogen includes fluorine, chlorine, bromine, or iodine. A specific example of such an organic compound may include CF₃(CF₂)₅CH₂CH₂NCS.

The organic compound may be supplied to the surface 1a of the substrate 1 in a gaseous state or may be supplied to the surface 1a of the substrate 1 in a liquid state. However, the former may form a denser SAM 17 than the latter. Details thereof will be described later.

Next, in step S3 of FIG. 1, as illustrated in FIG. 2C, a raw material gas, which is a raw material of a second insulating film 18, is supplied to the surface 1a of the substrate 1, so that the second insulating film 18 is formed in the first region A1 while inhibiting formation of the second insulating film 18 in the second region A2 using the SAM 17. The second insulating film 18 is formed on the insulating film 11 and is not formed on the metal film 12.

The SAM 17 is formed not only in the second region A2 but also in the third region A3, as described above. In this case, in step S3, the second insulating film 18 is formed in the first region A1 while inhibiting formation of the second insulating film 18 using the SAM 17 in the second region A2 and the third region A3. The second insulating film 18 is formed on the insulating film 11 and is not formed on the metal film 12 and the barrier film 13. According to the present embodiment, this may reduce a wiring resistance of the substrate 1 compared to the case in which the second insulating film 18 is formed on the barrier film 13.

The second insulating film 18 is formed by a chemical vapor deposition (CVD) method or an atomic layer deposition (ALD) method. The second insulating film 18 is not particularly limited and may be, for example, an AlO film, a SiO film, a SiN film, a ZrO film, or an HfO film. Here, the AlO film means a film containing aluminum (Al) and oxygen (O). An atomic ratio of Al to O in the AlO film is not limited to 1:1. This also holds true in the SiO film, the SiN film, the ZrO film, and the HfO film. The second insulating film 18 may be a film made of the same material as the insulating film 11 or a film made of a different material from the insulating film 11.

When the AlO film is formed by the ALD method, an Al-containing gas, such as a trimethylaluminum (TMA) gas, and an oxidizing gas, such as water vapor (H₂O gas), are alternately supplied to the surface 1a of the substrate 1. Since the water vapor is not adsorbed onto the hydrophobic SAM 17, AlO is selectively deposited on the first region A1. In addition to the Al-containing gas and the oxidizing gas, a modification gas such as a hydrogen gas may be supplied to the substrate 1. These raw material gases may be plasmarized to promote the chemical reaction. Further, these raw material gases may also be heated to promote the chemical reaction.

When the HfO film is formed by the ALD method, an Hf-containing gas, such as a tetrakisdimethylamidohafnium (TDMAH:Hf[N(CH₃)₂]₄) gas, and an oxidizing gas, such as water vapor (H₂O gas), are alternately supplied to the surface 1a of the substrate 1. Since the water vapor is not adsorbed onto the hydrophobic SAM 17, HfO is selectively deposited on the first region A1. In addition to the Hf-containing gas and the oxidizing gas, a modification gas such as a hydrogen gas may be supplied to the substrate 1. These raw material gases may be plasmarized to promote the chemical reaction. These raw material gases may also be heated to promote the chemical reaction.

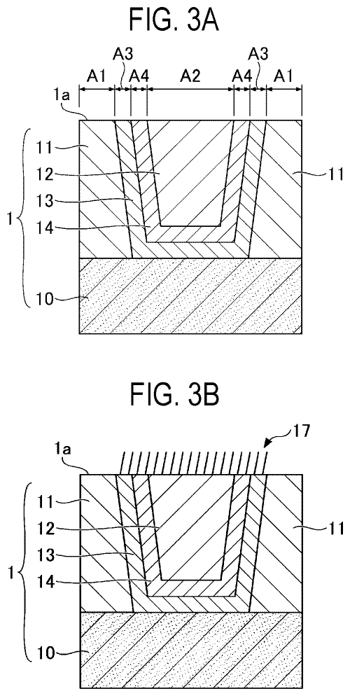

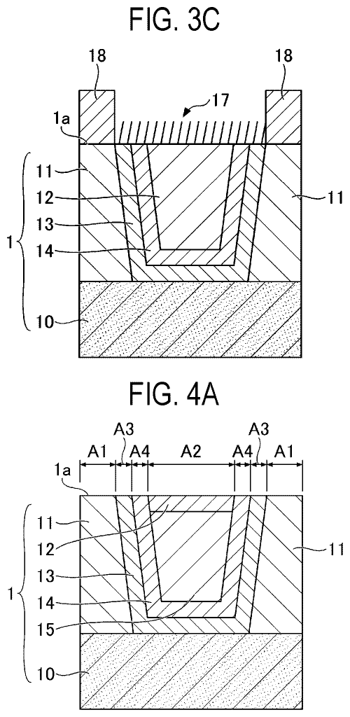

Processing on the substrate 1 according to a first modification will now be described with reference to FIGS. 3A to 3C. As illustrated in FIG. 3A, the substrate 1 of this modification further includes, on the surface 1a thereof, a fourth region A4 on which a liner film 14 is exposed. The fourth region A4 is formed between the second region A2 and the third region A3. The liner film 14 is formed on the barrier film 13 to support formation of the metal film 12. The metal film 12 is formed on the liner film 14. The liner film 14 is not particularly limited and may be, for example, a Co film or a Ru film.

Table 2 summarizes specific examples of the insulating film 11, the metal film 12, the barrier film 13, and the liner film 14.

TABLE 2

| Insulating film | Metal film | Barrier film | Liner film |
|---|---|---|---|
| SiO film | Cu film | TaN film | Co film |
| SiN film | | TiN film | Ru film |
| SiOC film | | | |
| SiON film | | | |
| SiOCN film | | | |

A combination of the insulating film 11, the metal film 12, the barrier film 13, and the liner film 14 is not particularly limited.

The isothiocyanate group of the organic compound, which is the raw material of the SAM 17, is more easily chemisorbed even onto the liner film 14 than onto the insulating film 11.

Therefore, in step S2 of the present modification, as illustrated in FIG. 3B, the organic compound may be selectively chemisorbed onto the second region A2, the third region A3, and the fourth region A4 among the first region A1, the second region A2, the third region A3, and the fourth region A4, so that the SAM 17 may be formed. The SAM 17 is not formed in the first region A1.

In step S3 of this modification, as illustrated in FIG. 3C, a second insulating film 18 is formed in the first region A1 while inhibiting formation of the second insulating film 18 in the second region A2, the third region A3, and the fourth region A4 using the SAM 17. The second insulating film 18 is formed on the insulating film 11 and is not formed on the metal film 12, the barrier film 13, and the liner film 14. According to this modification, the wiring resistance of the substrate 1 may be reduced compared to the case in which the second insulating film 18 is formed on the barrier film 13 and the liner film 14.

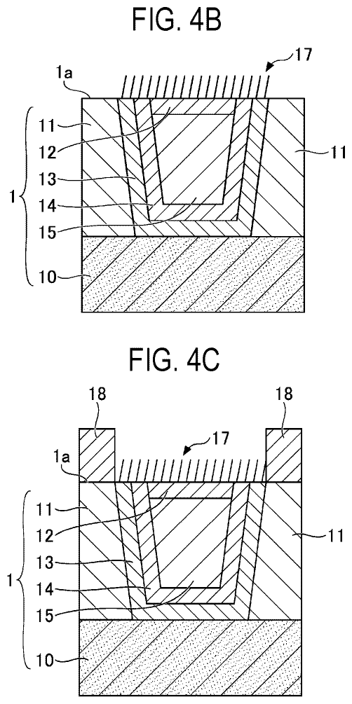

The processing on the substrate 1 according to a second modification will now be described with reference to FIGS. 4A to 4C. In the substrate 1 of this modification, as illustrated in FIG. 4A, the metal film 12 is a cap film. A second metal film 15 made of a metal different from the metal film 12 is embedded in the recess of the insulating film 11. The metal film 12 is formed on the second metal film 15, and the metal film 12 covers the second metal film 15.

Table 3 summarizes specific examples of the insulating film 11, the metal film (cap film) 12, the barrier film 13, the liner film 14, and the second metal film 15.

TABLE 3

| | | | | Second metal |
|---|---|---|---|---|
| Insulating film | Metal film | Barrier film | Liner film | film |
| SiO film | Cu film | TaN film | Co film | Cu film |
| SiN film | Ru film | TiN film | Ru film | |
| SiOC film | | | | |
| SiON film | | | | |
| SiOCN film | | | | |

A combination of the insulating film 11, the metal film 12, the barrier film 13, the liner film 14, and the second metal film 15 is not particularly limited.

In step S2 of this modification, as illustrated in FIG. 4B, the organic compound may be selectively chemisorbed onto the second region A2, the third region A3, and the fourth region A4 among the first region A1, the second region A2, the third region A3, and the fourth region A4, so that the SAM 17 may be formed. The SAM 17 is not formed in the first region A1.

In step S3 of this modification, as illustrated in FIG. 4C, the second insulating film 18 is formed in the first region A1 while inhibiting formation of the second insulating film 18 in the second region A2, the third region A3, and the fourth region A4 using the SAM 17. The second insulating film 18 is formed on the insulating film 11 and is not formed on the metal film 12, the barrier film 13, and the liner film 14. According to this modification, the wiring resistance of the substrate 1 may be reduced compared to the case in which the second insulating film 18 is formed on the barrier film 13 and the liner film 14.

Next, a film forming apparatus 100 that implements the above-described film forming method will be described with reference to FIG. 5. As illustrated in FIG. 5, the film forming apparatus 100 includes a first processor 200A, a second processor 200B, a transferer 400, and a controller 500. The first processor 200A performs step S2 of FIG. 1. The second processor 200B performs step S3 of FIG. 1. The first processor 200A and the second processor 200B have similar structures. Therefore, all of steps S2 and S3 of FIG. 1 may be implemented only by the first processor 200A. The transferer 400 transfers the substrate 1 to the first processor 200A and the second processor 200B. The controller 500 controls the first processor 200A, the second processor 200B, and the transferer 400.

The transferer 400 includes a first transfer chamber 401 and a first transfer mechanism 402. An internal atmosphere of the first transfer chamber 401 is an atmospheric atmosphere. The first transfer mechanism 402 is provided inside the first transfer chamber 401. The first transfer mechanism 402 includes an arm 403 that holds the substrate 1 and travels along a rail 404. The rail 404 extends in an arrangement direction of carriers C.

The transferer 400 includes a second transfer chamber 411 and a second transfer mechanism 412. An internal atmosphere of the second transfer chamber 411 is a vacuum atmosphere. The second transfer mechanism 412 is provided inside the second transfer chamber 411. The second transfer mechanism 412 includes an arm 413 that holds the substrate 1. The arm 413 is arranged to be movable in vertical and horizontal directions and rotatable about a vertical axis. The first processor 200A and the second processor 200B are connected to the second transfer chamber 411 via different gate valves G.

Further, the transferer 400 includes a load lock chamber 421 provided between the first transfer chamber 401 and the second transfer chamber 411. An internal atmosphere of the load lock chamber 421 is switched between a vacuum atmosphere and an atmospheric atmosphere by a pressure regulating mechanism (not illustrated). Thus, the interior of the second transfer chamber 411 may always be maintained in a vacuum atmosphere. In addition, it is possible to suppress gas from flowing into the second transfer chamber 411 from the first transfer chamber 401. Gate valves G are provided between the first transfer chamber 401 and the load lock chamber 421 and between the second transfer chamber 411 and the load lock chamber 421.

The controller 500 is, for example, a computer, and includes a central processing unit (CPU) 501 and a computer-readable storage medium 502 such as a memory. The storage medium 502 stores a program for controlling various processes executed in the film forming apparatus 100. The controller 500 controls the operation of the film forming apparatus 100 by causing the CPU 501 to execute the program stored in the storage medium 502. The controller 500 controls the first processor 200A, the second processor 200B, and the transferer 400 to implement the film forming method described above.

Next, the operation of the film forming apparatus 100 will be described. First, the first transfer mechanism 402 takes the substrate 1 out of the carrier C and transfers the taken-out substrate 1 to the load lock chamber 421. Subsequently, the first transfer mechanism 402 is withdrawn from the load lock chamber 421. Subsequently, an internal atmosphere of the load lock chamber 421 is switched from the atmospheric atmosphere to the vacuum atmosphere. Thereafter, the second transfer mechanism 412 takes the substrate 1 out of the load lock chamber 421 and transfers the taken-out substrate 1 to the first processor 200A.

Subsequently, the first processor 200A performs step S2. Thereafter, the second transfer mechanism 412 takes the substrate 1 out of the first processor 200A and transfers the taken-out substrate 1 to the second processor 200B. During this time, the ambient atmosphere of the substrate 1 may be maintained as the vacuum atmosphere so that oxidation of the substrate 1 may be suppressed.

Subsequently, the second processor 200B performs step S3. Thereafter, the second transfer mechanism 412 takes the substrate 1 out of the second processor 200B and transfers the taken-out substrate 1 to the load lock chamber 421. Thereafter, the second transfer mechanism 412 is withdrawn from the load lock chamber 421. Subsequently, the internal atmosphere of the load lock chamber 421 is switched from the vacuum atmosphere to the atmospheric atmosphere. Thereafter, the first transfer mechanism 402 takes the substrate 1 out of the load lock chamber 421 and accommodates the taken-out substrate 1 in the carrier C. Then, processing of the substrate 1 is completed.

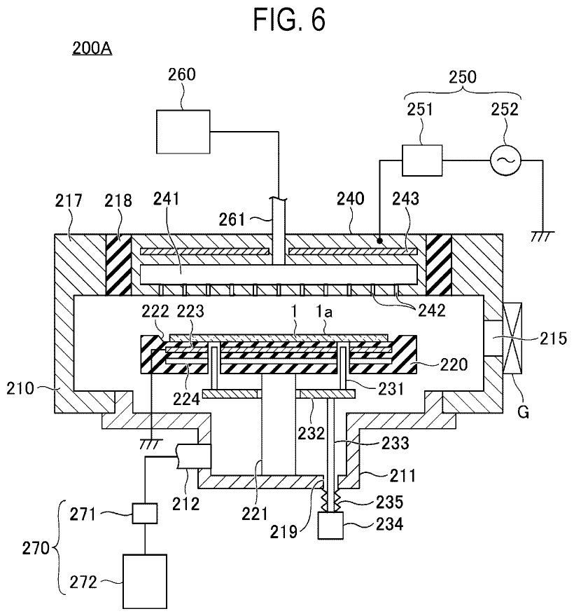

Next, the first processor 200A will be described with reference to FIG. 6. Since the second processor 200B is configured similarly to the first processor 200 A, the illustration and description of the second processor 200B will be omitted.

The first processor 200A includes a substantially cylindrical airtight processing container 210. An exhaust chamber 211 is provided at the center of a bottom wall of the processing container 210. The exhaust chamber 211 has, for example, a substantially cylindrical shape that projects downward. An exhaust pipe 212 is connected to the exhaust chamber 211, for example, on a side surface of the exhaust chamber 211.

An exhaust source 272 is connected to the exhaust pipe 212 via a pressure controller 271. The pressure controller 271 includes a pressure regulating valve, such as a butterfly valve. The exhaust pipe 212 is configured to depressurize the interior of the processing container 210 by the exhaust source 272. The pressure controller 271 and the exhaust source 272 constitute a gas discharge mechanism 270 that discharges a gas in the processing container 210.

A transfer port 215 is provided on a side surface of the processing container 210. The transfer port 215 is opened and closed by a gate valve G. Loading and unloading of the substrate 1 between the interior of the processing container 210 and the second transfer chamber 411 (see FIG. 5) is performed via the transfer port 215.

A stage 220, which is a holder for holding the substrate 1, is provided inside the processing container 210. The stage 220 holds the substrate 1 horizontally with the surface 1a of the substrate 1 oriented upward. The stage 220 is formed in a substantially circular shape in a plan view and is supported by a support member 221. A substantially circular recess 222 is formed in the surface of the stage 220 to place the substrate 1 having a diameter of, for example, 300 mm. The recess 222 has an inner diameter slightly larger than a diameter of the substrate 1. A depth of the recess 222 is substantially the same as, for example, a thickness of the substrate 1. The stage 220 is made of, for example, a ceramic material such as aluminum nitride (AlN). The stage 220 may also be made of a metal material such as nickel (Ni). A guide ring that guides the substrate 1 may be provided at a peripheral edge of the surface of the stage 220 instead of the recess 222.

In the stage 220, for example, a grounded lower electrode 223 is embedded. A heating mechanism 224 is embedded below the lower electrode 223. The heating mechanism 224 heats the substrate 1 placed on the stage 220 to a set temperature by being supplied with power from a power supply (not illustrated) based on a control signal from the controller 500 (see FIG. 5). When the entire stage 220 is made of metal, the entire stage 220 may function as a lower electrode. Thus, the lower electrode 223 does not need to be embedded in the stage 220. The stage 220 is provided with a plurality of (e.g., three) lifting pins 231 for holding and lifting the substrate 1 placed on the stage 220. A material of the lifting pins 231 may be, for example, ceramic, such as alumina (Al₂O₃), or quartz. Lower ends of the lifting pins 231 are attached to a support plate 232. The support plate 232 is connected to a lifting mechanism 234 provided outside the processing container 210 via a lifting shaft 233.

The lifting mechanism 234 is installed, for example, in a lower portion of the exhaust chamber 211. A bellows 235 is provided between an opening 219 for the lifting shaft 233 formed in a lower surface of the exhaust chamber 211 and the lifting mechanism 234. The support plate 232 may have a shape that can be raised and lowered without interfering with the support member 221 of the stage 220. The lifting pins 231 are configured to be capable of elevating between above the surface of the stage 220 and below the surface of the stage 220 by the lifting mechanism 234.

A gas supplier 240 is provided on a top wall 217 of the processing container 210 via an insulating member 218. The gas supplier 240 forms an upper electrode and faces the lower electrode 223. A high-frequency power supply 252 is connected to the gas supplier 240 via a matcher 251. By supplying high frequency power of 450 kHz to 100 MHz from the high frequency power supply 252 to the upper electrode (the gas supplier 240), a high frequency electric field is generated between the upper electrode (the gas supplier 240) and the lower electrode 223 to generate capacitively coupled plasma. A plasma generator 250 that generates plasma includes the matcher 251 and the high-frequency power supply 252. The plasma generator 250 may be a plasma generator that generates other plasma, such as inductively coupled plasma, without being limited to the capacitively coupled plasma.

The gas supplier 240 includes a hollow gas supply chamber 241. A plurality of holes 242 for dispersedly supplying a processing gas into the processing container 210 are arranged, for example, uniformly, in a lower surface of the gas supply chamber 241. In the gas supplier 240, a heating mechanism 243 is embedded, for example, above the gas supply chamber 241. The heating mechanism 243 is heated to a set temperature by being supplied with power from a power supply (not illustrated) based on a control signal from the controller 500.

A gas supply mechanism 260 is connected to the gas supply chamber 241 via a gas supply path 261. The gas supply mechanism 260 supplies a gas used in at least one of steps S2 and S3 of FIG. 1 to the gas supply chamber 241 via the gas supply path 261. Although not illustrated, the gas supply mechanism 260 includes an individual pipe, an on-off valve provided in the individual pipe, and a flow rate controller provided in the individual pipe, for each type of gas. When the on-off valve opens the individual pipe, a gas is supplied from a source to the gas supply path 261. The supply of the gas is controlled by the flow controller. On the other hand, when the on-off valve closes the individual pipe, the supply of the gas from the source to the gas supply path 261 is stopped.

### Experimental Example 1

In Experimental Example 1, the Cu substrate was prepared, a natural oxide film on the surface of the Cu substrate was removed, the raw material of the SAM was supplied to the surface of the Cu substrate, and the Cu substrate was heated to fix the SAM. Thereafter, the surface state of the Cu substrate was measured using an X-ray photoelectron spectroscopy (XPS) device.

In the removal of the natural oxide film, the Cu substrate was immersed in an aqueous solution at 65 degrees C. with a citric acid concentration of 1% by volume for 1 minute, the Cu substrate was washed with pure water, and then the Cu substrate was dried with a N₂ gas.

In the supply of the raw material of the SAM, the Cu substrate was immersed in a toluene solution at 85 degrees C. with a SAM raw material concentration of 0.1% by volume for 5 minutes, the Cu substrate was washed with toluene at 85 degrees C., and then the Cu substrate was dried with the N₂ gas. CF₃(CF₂)₅CH₂CH₂NCS was used as the raw material of the SAM.

In the fixing of the SAM, the Cu substrate was heated for 10 minutes on a hot plate at 60 degrees C., and then was heated for 4 minutes on the hot plate at 120 degrees C.

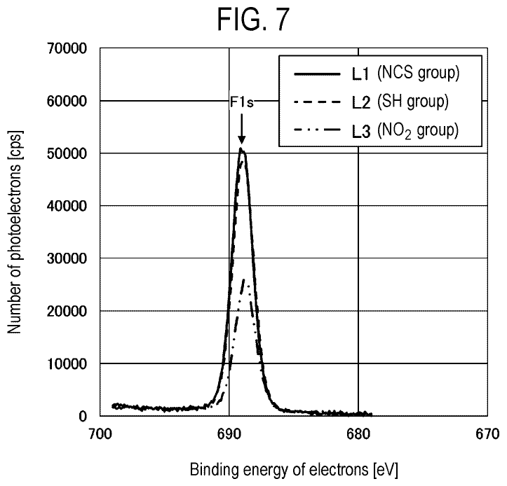

FIG. 7 illustrates results obtained by measuring, using XPS, a surface state of the Cu substrate obtained from Experimental Example 1. FIG. 7 also illustrates results obtained by processing the Cu substrate under the same condition except that CF₃(CF₂)₇CH₂CH₂SH or CF₃(CF₂)₅CH₂CH₂NO₂ is used instead of CF₃(CF₂)₅CH₂CH₂NCS as the raw material of the SAM.

In FIG. 7, a solid line L1 illustrates a result obtained when using CF₃(CF₂)₅CH₂CH₂NCS as the raw material of the SAM, and a dashed line L2 illustrates a result obtained when using CF₃(CF₂)₇CH₂CH₂SH as the raw material of the SAM. A dash-double-dotted line L3 illustrates a result obtained when using CF₃(CF₂)₅CH₂CH₂NO₂ as the material of the SAM.

As is apparent from FIG. 7, in any case in which the head group of the raw material of the SAM is the isothiocyanate group (NCS group), the thiol group (SH group), or the nitro group (NO₂ group), the peak of fluorine (F), which is a constituent element of the SAM, is observed. Thus, in any of the cases, it may be appreciated that the SAM has been formed on the surface of the Cu substrate.

As is apparent from FIG. 7, when the head group of the SAM raw material is the isothiocyanate group (NCS group), the peak of fluorine is larger and the formation density of the SAM is higher than when the head group of the SAM raw material is the thiol group (SH group) and the nitro group (NO₂ group). The higher the formation density of the SAM, the more the SAM tends to inhibit formation of the second insulating film in step S3 in FIG. 1.

In FIG. 7, the solid line L1 is a result obtained when the SAM raw material has 13 fluorine atoms in one molecule, whereas the dashed line L2 is a result obtained when the SAM raw material has 17 fluorine atoms in one molecule. Therefore, in FIG. 7, when the vertical axis is replaced from the “number of photoelectrons” to the “formation density of molecules,” it is considered that a difference between the solid line L1 and the dashed line L2 increases.

The dash-double-dotted line L3 is also a result obtained when the SAM raw material has 13 fluorine atoms in one molecule, similar to the solid line L1. Therefore, in FIG. 7, when the vertical axis is replaced from the “number of photoelectrons” to the “formation density of the molecule,” it is considered that the difference between the dash-double-dotted line L3 and the dashed line L2 is reduced, and it is also conceivable that a magnitude relationship is reversed.

### Experimental Example 2

In Experimental Example 2, the Cu substrate was processed under the same conditions as Experimental Example 1 except that the raw material of SAM was supplied to the surface of the Cu substrate in a gaseous state instead of being supplied in a liquid state. Specifically, in the supply of the raw material of the SAM in Experimental Example 2, first, both a toluene solution with a SAM raw material concentration of 0.1% by volume and the Cu substrate were accommodated in a container, and the Cu substrate was positioned above a liquid surface of the toluene solution. In this state, the entire container was uniformly heated from the outside with a heater. A heating temperature was 85 degrees C. and a heating time was 5 minutes. Thus, the raw material of the SAM was supplied in a gaseous state to the surface of the Cu substrate. CF₃(CF₂)₅CH₂CH₂NCS was used as the raw material of the SAM.

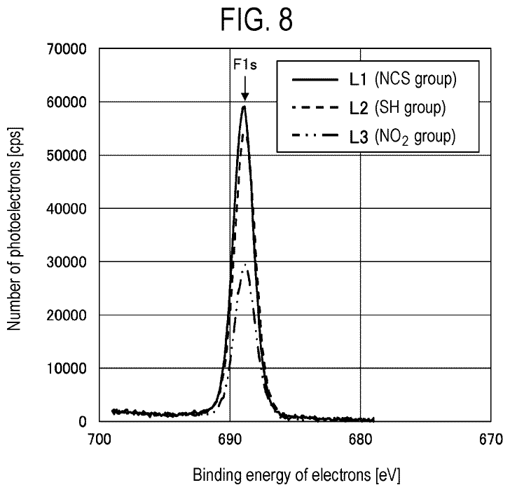

FIG. 8 illustrates results obtained by measuring, using XPS, the surface state of the Cu substrate obtained from Experimental Example 2. FIG. 8 also illustrates results obtained when processing the Cu substrate under the same condition except that CF₃(CF₂)₇CH₂CH₂SH or CF₃(CF₂)₅CH₂CH₂NO₂ is used instead of CF₃(CF₂)₅CH₂CH₂NCS as the raw material of the SAM.

In FIG. 8, a solid line L1 illustrates a result obtained when using CF₃(CF₂)₅CH₂CH₂NCS as the raw material of the SAM, and a dashed line L2 illustrates a result obtained when using CF₃(CF₂)₇CH₂CH₂SH as the raw material of the SAM. A dash-double-dotted line L3 illustrates a result obtained when using CF₃(CF₂)₅CH₂CH₂NO₂ as the material of the SAM.

As is apparent from FIG. 8, in any case in which the head group of the raw material of the SAM is the isothiocyanate group (NCS group), the thiol group (SH group), or the nitro group (NO₂ group), the peak of fluorine (F), which is a constituent element of the SAM, is observed. Thus, in any of the cases, it may be appreciated that the SAM has been formed on the surface of the Cu substrate.

In any case in which the head group of the raw material of the SAM is the isothiocyanate group (NCS group), the thiol group (SH group), or the nitro group (NO₂ group), the peak of fluorine in FIG. 8 was greater than the peak of fluorine in FIG. 7. Thus, it may be appreciated that, when the SAM is supplied to the surface of the Cu substrate in a gaseous state instead of being supplied in a liquid state, the SAM is formed at a high density on the surface of the Cu substrate.

### Experimental Example 3

In Experimental Example 3, the substrate was processed under the same conditions as in Example 1 except that various substrates were prepared instead of the Cu substrate. As substrates, a substrate including a Co film on a surface thereof, a substrate including a Ru film on a surface thereof, a substrate including a W film on a surface thereof, a substrate including a TiN film on a surface thereof, and a substrate including a SiO film on a surface thereof were prepared. The SiO film was a silicon thermal oxide film.

In the supply of the raw material of the SAM in Experimental Example 3, similarly to the supply of the raw material of the SAM in Experimental Example 1, the substrate was immersed in a toluene solution at 85 degrees C. with a SAM raw material concentration of 0.1% by volume for 5 minutes, the substrate was washed with toluene at 85 degrees C., and then the substrate was dried with the N₂ gas. CF₃(CF₂)₅CH₂CH₂NCS was used as the raw material of the SAM.

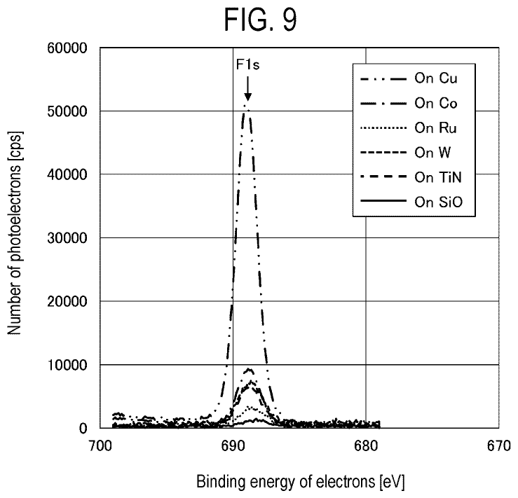

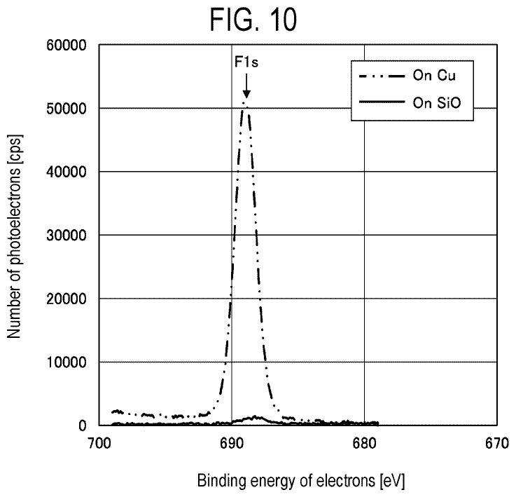

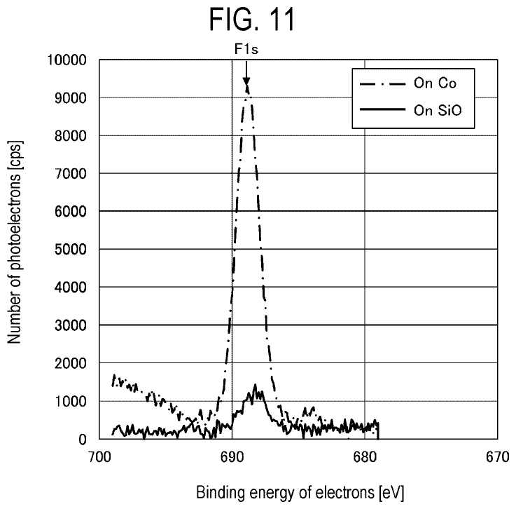

FIG. 9 illustrates results obtained by measuring, using XPS, surface states of various substrates obtained from Experimental Example 3. FIG. 9 also illustrates a result obtained by measuring, using XPS, the surface state of the Cu substrate represented by the solid line L1 in FIG. 7 (result of Experimental example 1). FIGS. 10 to 14 are diagrams illustrating the results of some substrates illustrated in FIG. 9. As is apparent from FIGS. 9 to 14, it may be appreciated that an organic compound containing the isothiocyanate group (NCS group) as the head group is more easily adsorbed on Cu, Co, Ru, W, or TiN than on SiO.

Thus, it may be appreciated that the organic compound containing the isothiocyanate group (NCS group) as the head group may form the SAM not only in a region on which the metal film is exposed, but also in a region on which the barrier film is exposed or a region on which the liner film is exposed. The SAM may not only inhibit formation of the second insulating film in the metal film, but also inhibit formation of the second insulating film in the barrier film or the liner film. Therefore, the wiring resistance of the substrate 1 may be reduced.

### Reference Example 1

In Reference Example 1, the substrate was processed under the same conditions as in Experimental Example 3 except that an organic compound having a nitro group (NO₂ group) as the head group was used as the raw material of the SAM. As substrates, a substrate including a Co film on a surface thereof, a substrate including a Ru film on a surface thereof, a substrate including a W film on a surface thereof, a substrate including a TiN film on a surface thereof, and a substrate including a SiO film on a surface thereof were prepared. The SiO film was a silicon thermal oxide film.

In the supply of the raw material of the SAM in Reference Example 1, similarly to the supply of the raw material of SAM in Experimental Example 1, the substrate was immersed in a toluene solution at 85 degrees C. with an SMA raw material concentration of 0.1% by volume for 5 minutes, the substrate was washed with toluene at 85 degrees C., and then the substrate was dried with the N₂ gas. CF₃(CF₂)₅CH₂CH₂NO₂ was used as the raw material of SAM.

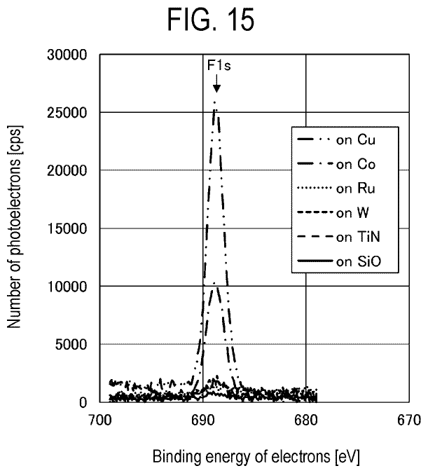

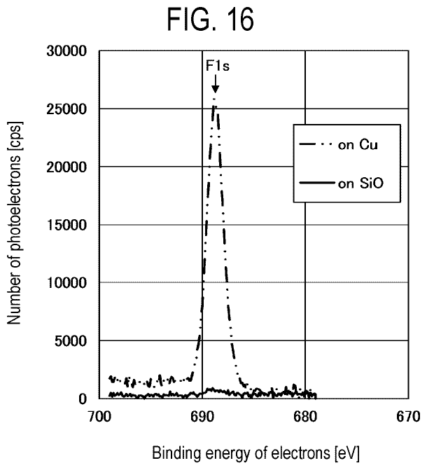

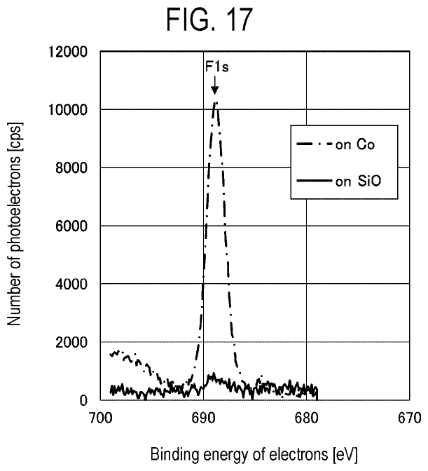

FIG. 15 illustrates results obtained by measuring, using XPS, surface states of various substrates obtained from Reference Example 1. FIG. 15 also illustrates a result obtained by measuring, using XPS, the surface state of the Cu substrate represented by the dash-double-dotted line L3 in FIG. 7. FIGS. 16 to 20 are diagrams illustrating the results of some substrates illustrated in FIG. 15. As is apparent from FIGS. 15 to 20, it may be appreciated that an organic compound containing the nitro group (NO₂ group) as the head group is more easily adsorbed on Cu, Co, Ru, W, or TiN than on SiO.

Thus, it may be appreciated that the organic compound containing the nitro group (NO₂ group) as the head group may form the SAM not only in a region on which the metal film is exposed, but also in a region on which the barrier film is exposed or a region on which the liner film is exposed. The SAM may not only inhibit formation of the second insulating film in the metal film, but also inhibit formation of the second insulating film in the barrier film or the liner film. Therefore, the wiring resistance of the substrate 1 may be reduced.

### Comparison Between Experimental Example 3 and Reference Example 1

The peak of fluorine represented by a dash-double-dotted line in FIG. 10 is greater than the peak of fluorine represented as a dash-doubled-dotted line in FIG. 16. Thus, it may be appreciated that, when the head group of the raw material of the SAM is the isothiocyanate group (NCS group), the SAM is formed at a higher density on the surface of the Cu substrate than when the head group is the nitro group (NO₂ group).

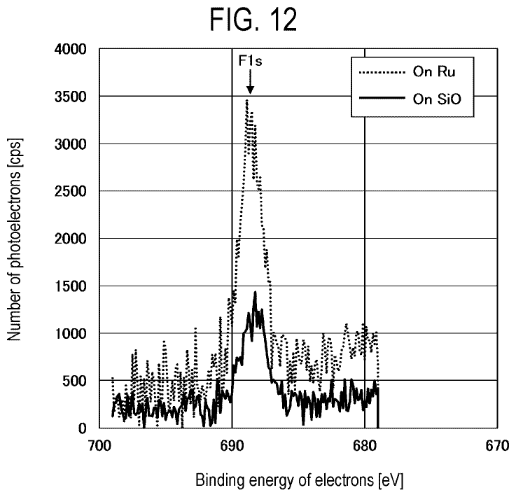

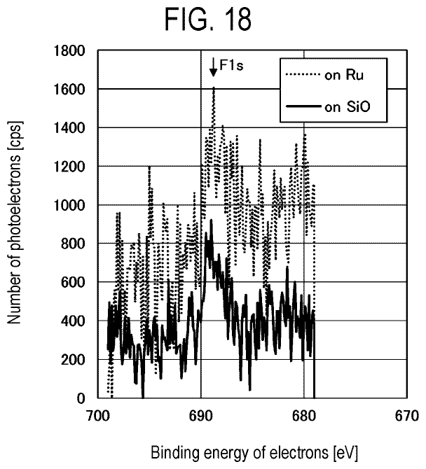

The peak of fluorine represented by a dashed line in FIG. 12 is greater than the peak of fluorine represented as a dashed line in FIG. 18. Thus, it may be appreciated that, when the head group of the raw material of the SAM is the isothiocyanate group (NCS group), the SAM is formed at a higher density on the surface of the Ru film than when the head group is the nitro group (NO₂ group).

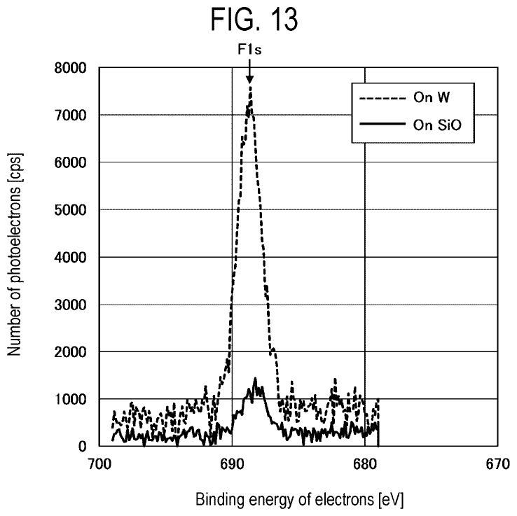

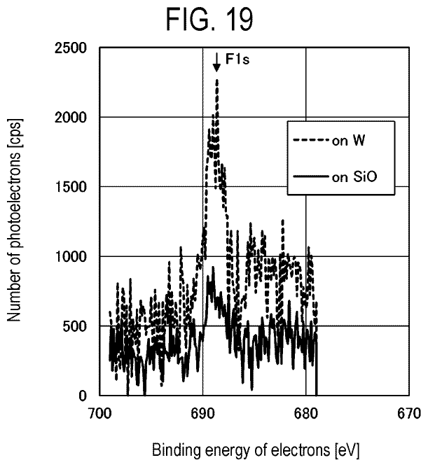

The peak of fluorine represented by a dashed line in FIG. 13 is greater than the peak of fluorine represented as a dashed line in FIG. 19. Thus, it may be appreciated that, when the head group of the raw material of the SAM is the isothiocyanate group (NCS group), the SAM is formed at a higher density on the surface of the W film than when the head group is the nitro group (NO₂ group).

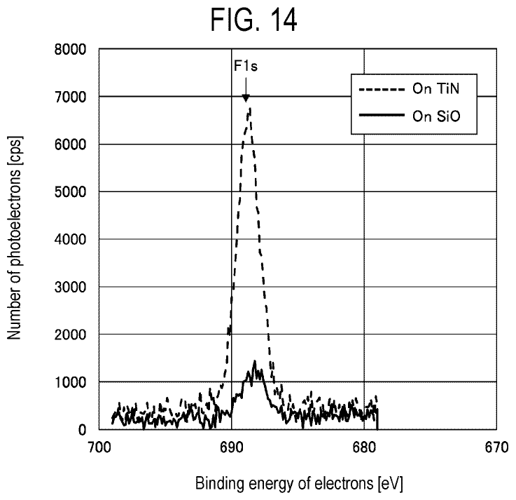

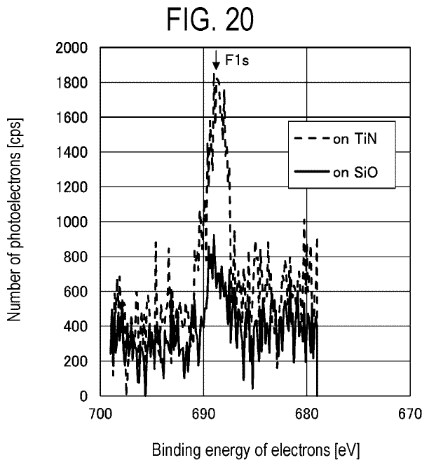

The peak of fluorine represented by a dashed line in FIG. 14 is greater than the peak of fluorine represented as a dashed line in FIG. 20. Thus, it may be appreciated that, when the head group of the raw material of the SAM is the isothiocyanate group (NCS group), the SAM is formed at a higher density on the surface of the TiN film than when the head group is the nitro group (NO₂ group).

As described above, it may be appreciated that, when the head group of the raw material of the SAM is the isothiocyanate group (NCS group), the SAM is formed at a higher density on the surfaces of various films than when the head group is the nitro group (NO₂ group). The higher the formation density of the SAM, the more the SAM tends to inhibit formation of the second insulating film in step S3 in FIG. 1.

While the embodiments of the film forming method and the film forming apparatus according to the present disclosure have been described above, the present disclosure is not limited to the above embodiments. Various changes, modifications, substitutions, additions, deletions, and combinations are possible within the scope of the claims. These naturally fall within the technical scope of the present disclosure.

This application claims priority based on Japanese Patent Application No. 2021-132242 filed with the Japan Patent Office on Aug. 16, 2021, and the entirety of Japanese Patent Application No. 2021-132242 is incorporated in this application.

### EXPLANATION OF REFERENCE NUMERALS

1: substrate, 1a: surface, 11: insulating film, 12: metal film, 17: self-assembled monolayer (SAM), 18: second insulating layer, A1: first region, A2: second region

1-25. (canceled)

26. A film forming method, comprising:
preparing a substrate having a first region on which a first insulating film is exposed and a second region on which a metal film is exposed, on a surface of the substrate;
supplying, to the surface of the substrate, an organic compound including an isothiocyanate group (NCS group) as a head group which is a raw material of a self-assembled monolayer, and forming the self-assembled monolayer by selectively adsorbing the organic compound onto the second region among the first region and the second region; and
supplying, to the surface of the substrate, a raw material gas which is a raw material of a second insulating film, and forming the second insulating film in the first region while inhibiting formation of the second insulating film in the second region using the self-assembled monolayer.

27. The film forming method of claim 26, wherein the first insulating film has a recess in the surface of the substrate, and the metal film is formed in the recess.

28. The film forming method of claim 27, wherein the substrate further has, on the surface, a third region on which a barrier film is exposed,
wherein the self-assembled monolayer is formed by selectively adsorbing the organic compound onto the second region and the third region among the first region, the second region, and the third region, and
wherein the second insulating film is formed in the first region while inhibiting formation of the second insulating film in the second region and the third region using the self-assembled monolayer.

29. The film forming method of claim 28, wherein the barrier film is a TaN film or a TiN film.

30. The film forming method of claim 29, wherein the substrate further includes, on the surface, a fourth region on which a liner film is exposed,
wherein the self-assembled monolayer is formed by selectively adsorbing the organic compound onto the second region, the third region, and the fourth region among the first region, the second region, the third region, and the fourth region, and
wherein the second insulating film is formed in the first region while inhibiting formation of the second insulating film in the second region, the third region, and the fourth region using the self-assembled monolayer.

31. The film forming method of claim 30, wherein the liner film is a Co film or a Ru film.

32. The film forming method of claim 27, wherein a second metal film made of a metal different from the metal film is embedded in the recess, and
wherein the metal film is a cap film covering the second metal film.

33. The film forming method of claim 32, wherein the second metal film is a Cu film, and
wherein the cap film, which is the metal film, is a Co film or a Ru film.

34. The film forming method of claim 27, wherein the metal film is a Cu film or a W film.

35. The film forming method of claim 27, wherein the first insulating film is a SiN film, a SiO film, a SiOC film, a SiON film, or a SiOC film.

36. The film forming method of claim 26, further comprising: supplying the organic compound in a gaseous state to the surface of the substrate.

37. The film forming method of claim 28, wherein the substrate further includes, on the surface, a fourth region on which a liner film is exposed,
wherein the self-assembled monolayer is formed by selectively adsorbing the organic compound onto the second region, the third region, and the fourth region among the first region, the second region, the third region, and the fourth region, and
wherein the second insulating film is formed in the first region while inhibiting formation of the second insulating film in the second region, the third region, and the fourth region using the self-assembled monolayer.

38. A film forming apparatus, comprising:
a processing container;
a holder provided inside the processing container and configured to hold a substrate;
a gas supply mechanism configured to supply a gas to an interior of the processing container;
a gas discharge mechanism configured to discharge the gas from the interior of the processing container;
a transfer mechanism configured to load or unload the substrate into or from the processing container; and
a controller configured to control the gas supply mechanism, the gas discharge mechanism, and the transfer mechanism to execute the film forming method of claim 26.
